(19) United States
(12) Patent Application Publication
(10) Pub. No.: US 2012/0164848 A1
(43) Pub. Date: Jun. 28, 2012

(54) METHOD FOR FORMING NITRIDE FILM

(75) Inventors: Motoki FUJII, Tokyo (JP); Masanobu MATSUNAGA, Yamanashi (JP); Kazuya YAMAMOTO, Yamanashi (JP); Kota UMEZAWA, Yamanashi (JP)

(73) Assignees: Tokyo Electron Limited, Tokyo (JP); Elpida Memory, Inc., Tokyo (JP)

(21) Appl. No.: 13/338,288

(22) Filed: Dec. 28, 2011

(30) Foreign Application Priority Data
Dec. 28, 2010 (JP) 2010-293379

(51) Int. Cl. H01L 21/318

(52) U.S. Cl. 438/791; 257/E21.293

(57) ABSTRACT

A plasma-assisted ALD method using a vertical furnace and being performed by repeating a cycle until a desired film thickness is obtained is disclosed. The cycle comprises introducing a source gas containing a source to be nitrided, adsorbing, purging, introducing a nitriding gas and nitriding the source, and then, purging. A flow rate of a second carrier gas during introduction of the nitriding gas is reduced relative to that of a first carrier gas during introduction of the source gas. Particularly, a flow ratio of NH₃ gas as the nitriding gas to N₂ gas as the second carrier gas is 50:3 or less.

### BACKGROUND OF THE INVENTION

1. Field of the Invention

The invention relates to a method for forming a nitride film, and more particularly to a method for forming a nitride film on a semiconductor wafer having a high density pattern formed thereon, using a batch-type vertical plasma-assisted ALD (Atomic Layer Deposition) apparatus.

2. Description of the Related Art

In semiconductor devices, tungsten (W), a refractory metal, has been generally used as a wiring in portions where heat resistance is required.

Also, in semiconductor devices having multi-layer wiring structures, an interlayer dielectric film is formed to electrically insulate the wiring of each layer from one another, but as the interlayer dielectric film, a silicon oxide film formed by CVD (Chemical Vapor Deposition) process is used.

Tungsten (W) is easily oxidized in an oxygen atmosphere during formation of a silicon oxide film, and thereby produces tungsten oxide (WOx) having a much higher resistivity than tungsten (W). As a result, there are problems that the resistance of the wiring is increased and also the adhesion strength of the wiring is deteriorated due to the volume expansion thereof, etc.

In order to avoid the problems as described above, instead of forming a silicon oxide film directly after forming a W wiring, a technique is used in which exposed portions of the W wiring are firstly covered with a silicon nitride film as an anti-oxidation film, and then the silicon oxide film is formed thereon by the CVD process.

In order to form the silicon nitride film as the anti-oxidation film as described above, a low-pressure CVD process is used in which the silicon nitride film is deposited in a range of temperature from 630° C. to 680° C., using dichlorosilane (SiH₂Cl₂: hereinafter, referred to as “DCS”) and ammonia gas (NH₃) as source gases.

However, the formation of the silicon nitride film by the CVD process causes a nitriding of the surface of the W wiring. Thus nitrided tungsten (WN) still maintains electric conductivity, but compared with tungsten (W), the resistance value thereof is approximately 10 times higher, and hence there is a problem that a wiring having a sufficiently low resistance for a micro wiring cannot be obtained.

In this regard, JP 2008-112826 A discloses that, after forming a tungsten (W) wiring, the W wiring is covered with a silicon nitride film deposited by ALD process at a temperature of 550° C. or below using NH₃, which is radicalized by plasma, and DCS such that the nitriding of the surface of the tungsten (W) wiring can be inhibited, and thereby, allowing an increase of the wiring resistance to be prevented.

Also, because the deposition using the ALD process has a better step coverage, this deposition of the silicon nitride film is not limited to the formation of the anti-oxidation film for the tungsten (W) wiring, and can be effectively applied to a formation of a side wall for a high density wiring (e.g., a gate wiring for a memory cell transistor).

For such a plasma-assisted ALD silicon nitride film process, a vertical ALD apparatus 100 as shown in FIG. 1 is used. Such a batch-type vertical furnace is configured such that each of semiconductor wafers is supported on a respective quartz wafer boat 101 in a multistage manner at a predetermined pitch and then contained within a cylindrical-shaped vertical processing vessel 102. The wafer boat 101 can be universally rotated by a rotation mechanism 103 at a predetermined rotation speed during deposition. A heating mechanism 104 is installed on an outer circumference of the cylindrical-shaped vertical processing vessel (e.g., a quartz chamber) 102 and can heat the inside of the processing vessel 102 at a predetermined temperature. The apparatus 100 includes a flow path F1 through which sources gases can be directly supplied into the processing vessel 102, and a flow path F2 through which the sources gases can be supplied into the processing vessel via a plasma space 105 located between RF electrodes 106 for radicalizing thereof. DCS gas is directly supplied into the processing vessel 102 from the flow path F1, while NH₃ gas to be radicalized is introduced along the flow path F2 to the plasma space 105 and then introduced into the processing vessel 102. Alternatively, DCS gas can be also supplied into the processing vessel 102 along the flow path F2 through the plasma space 105 without applying any RF power. Each of the flow paths for supplying the source gases is provided with micro holes (not shown), referred to as “a gas injector,” to evenly supply the source gases onto the semiconductor wafer in each stage. In addition, an exhaust port 107 of the processing vessel is connected to an exhaust pump (not shown) such that a pressure of a deposition space can be regulated and an exhaust gas can be emitted.

The deposition of the silicon nitride film according to the ALD process is preformed by repeating a cycle until a desired film thickness is obtained, wherein the cycle comprises the steps of firstly supplying a deposition gas which contains DCS as a silicon source into the processing vessel such that the silicon source can be adsorbed; purging DCS not adsorbed; supplying a nitriding gas which contains ammonia gas radicalized by plasma into the processing vessel such that the adsorbed DCS can be decomposed and nitrided; and then purging.

When using the batch-type vertical furnace as described above, each of the source gases is adjusted in a flow rate and the like to be evenly supplied in a height direction.

DCS as a silicon source is evenly supplied inside the furnace, but the ammonia gas as a nitriding gas is different in radicalization degree between the bottom and upper portions inside the processing vessel, even if the supply amounts thereto are equal. This problem is caused in that, when mixing the ammonia gas as a source gas with nitrogen gas (N₂) as a carrier gas and introducing into a flow path, although the gas supply amounts, as shown in FIG. 2A, are equal between the bottom and upper portions inside the processing vessel, an RF applying time for the ammonia gas passing through the space 105 located between the RF electrodes 106, as shown in FIG. 2B, is shortened in the bottom portion inside the furnace such that the ammonia gas is introduced into a reaction space without being sufficiently radicalized. The reduction of the plasma processing time of the ammonia gas causes a production amount of the N radical to be reduced. Because of the reduction of the N radial at the bottom portion, an amount of the N radical reaching to a center portion of the wafer is reduced and therefore DCS is insufficiently nitrided. This causes a decrease in the film thickness of the nitride film on the center portion of the wafer. In particular, because, as a surface area of a pattern is become larger, a more amount of the radical will be consumed, and hence, the film thickness on the center portion of the water is easily reduced (hereafter, referred to as “a film thinning phenomenon”), leading to a problem that a uniformity in the film thickness within a wafer surface is deteriorated (due to a loading effect). Furthermore, the lager the diameter of the wafer, the more easily the loading effect will be caused.

In order to solve such a problem, a technique in which the wafer is not placed on boats of the bottom portion is considered, and rather leading to a problem that productivity is deteriorated.

### SUMMARY OF THE INVENTION

As a result of intensive studies on a solution for preventing the uniformity in the film thickness on the wafers in a furnace bottom portion from being deteriorated due to the loading effect in the plasma-assisted ALD process using the batch-type vertical furnace, the inventors have found that an influence of the loading effect can be suppressed by varying flow rates of the carrier gases between the introducing of the DCS gas and the introducing of the ammonia gas.

Specifically, according to one embodiment of the invention, there is a provided a method for forming a nitride film by ALD process using a batch-type vertical furnace, wherein the batch-type vertical furnace comprises boats configured to allow semiconductor wafers to be disposed within a reaction vessel in a multistage manner, a plasma space located between RF electrodes disposed along side surfaces of the reaction vessel, and a supply port configured to approximately evenly supply a gas from the plasma space onto the semiconductor wafer in each stage within the reaction vessel, wherein the method is preformed by repeating a cycle until a desired film thickness is obtained, the cycle comprising:
supplying a source gas containing a source to be nitrided and a first carrier gas onto the semiconductor wafer in each stage, such that the source is adsorbed onto a surface of the semiconductor wafer;
purging the portion of the source gas not adsorbed;
introducing a nitriding gas and a second carrier gas from a bottom to a top of the plasma space such that a radical is generated, and then supplying a gas containing the generated radical onto the semiconductor wafer in each stage to nitrify the absorbed source; and
purging the nitriding gas;
   wherein an amount of the second carrier gas supplied together with the nitriding gas is less than that of the first carrier gas supplied together with the source gas.

Particularly, in the method according to the invention, ammonia gas can be used as the nitriding gas, nitrogen gas can be used as the second carrier gas, and the amount of the second carrier gas during introduction of the nitriding gas can be set at a flow rate ratio of the nitriding gas to the second carrier gas of 50:3 or less.

According to the invention, a sufficient production amount of the radical can be also obtained in the bottom portion of the furnace, and hence, providing an improvement to the film thinning phenomenon due to the loading effect on the center portion of the wafer.

### BRIEF DESCRIPTION OF THE DRAWINGS

The above features and advantages of the invention will be more apparent from the following description of certain preferred embodiments taken in conjunction with the accompanying drawings, in which:

FIG. 1 is a schematic view showing an example of a batch-type vertical plasma-assisted ALD apparatus;

FIGS. 2A and 2B are conceptual diagrams showing problems to be solved by the invention;

FIG. 3 is a schematic cross-sectional view showing an example of a nitride film to be formed according to an embodiment of the invention;

FIG. 4 shows a difference in a film thickness between a center portion and a peripheral portion according to a flow rate of a carrier gas;

FIG. 5 is a SEM photographic image showing a film thinning phenomenon on the center portion of the wafer according to a related art;

FIG. 6 is a SEM photographic image showing that the film thinning phenomenon on the center portion of the wafer is improved according to the invention; and

FIG. 7 shows a difference in the film thickness between the center portion and the peripheral portion for each stage number from the lowermost stage according to a difference in the flow rate of the carrier gas.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the invention and that the invention is not limited to the embodiments illustrated for explanatory purpose.

In an embodiment below, a method for forming a silicon nitride film on word lines being become into gate electrodes formed in a line shape, in particular, gate electrodes of a MOS transistor serving as an active device in memory cells of DRAM, will be explained.

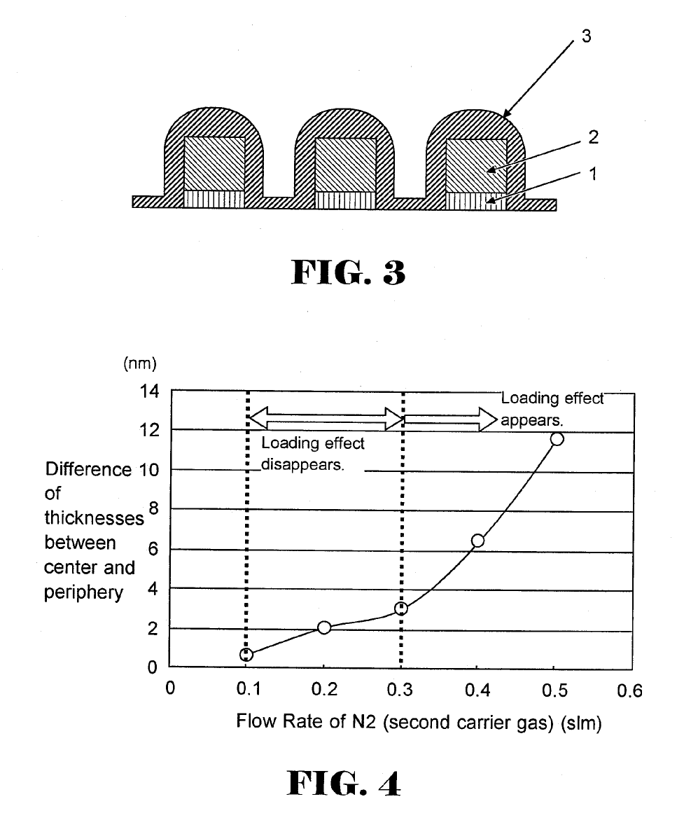

In a transistor formation region as shown in FIG. 3, a gate insulating film (not shown) made of a silicon oxide film is formed on a surface of the semiconductor substrate, for example, by a thermal oxidation method and the like.

A gate electrode 1 composed of a multilayer film comprising, for example, a polysilicon film and a metal film, is formed on the gate insulating film. As the polysilicon film, a doped polysilicon film formed by introducing impurities during deposition by the CVD method can be used. As the metal film, tungsten, tungsten silicide (WSi), or other refractory metals can be used. An insulation film 2, such as a silicon nitride film, is formed on the gate electrode 1, and a silicon nitride film 3 as a sidewall film is formed to cover the insulation film 2 by the ALD process. In this time, the silicon nitride film 3 was set to a thickness of 25 nm. Also, in this case, the wafer having a diameter of approximately 30 cm (12 inches) was used. However, the same effects were also obtained for a wafer size of 20 cm diameter.

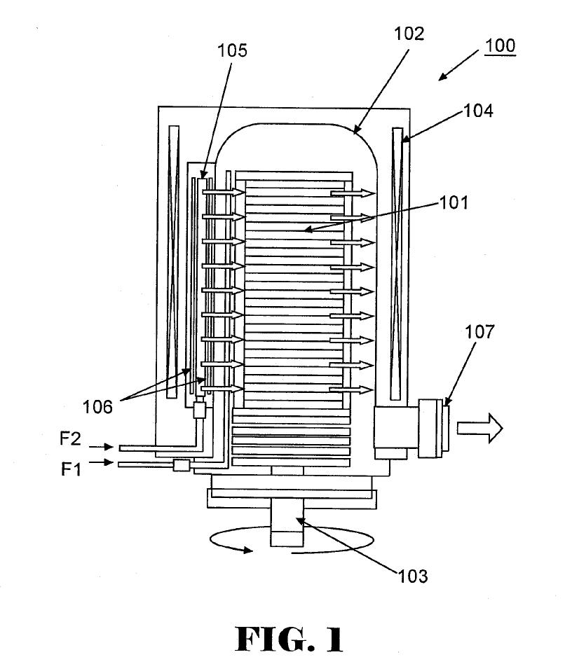

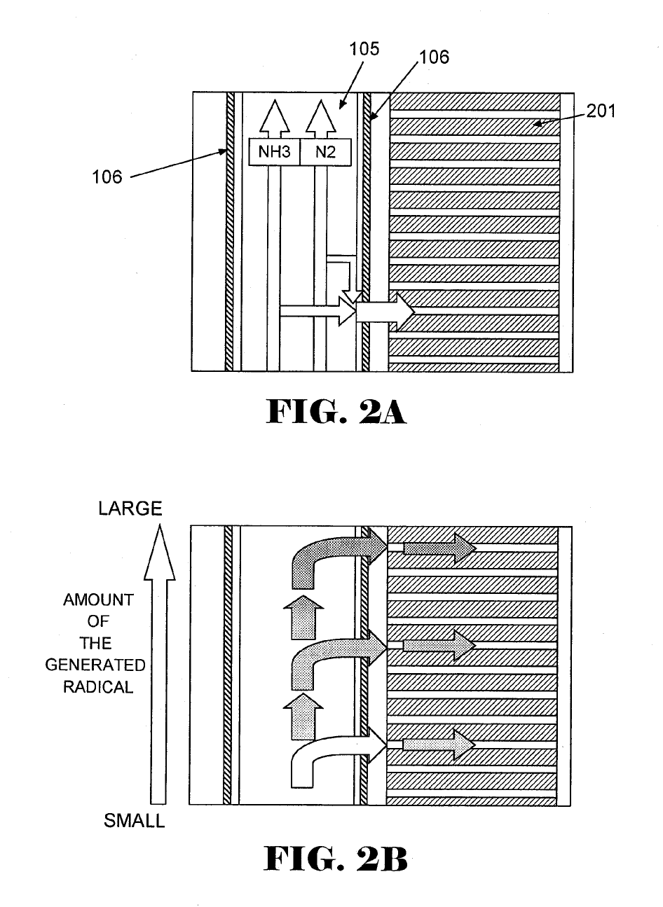

For this purpose, an apparatus (25 stage boats) as shown in FIG. 1 is used, and an ALD cycle is repeated until the thickness set to 25 nm is obtained, the ALD cycle comprising the following steps:
introducing DCS at a flow rate of 2 slm (standard litters per minute) and N₂ gas as a first carrier gas at a flow rate of 0.5 slm;
purging a deposition space by N₂ gas;
after purging, introducing ammonia gas at a flow rate of 5 slm, and N₂ gas as a second carrier gas with varying a flow rate thereof from 0.1 slm to 0.5 slm; and
purging the deposition space by N₂ gas.

The deposition temperature was 550° C. DCS was introduced into the reaction vessel along the flow path F1, and ammonia gas was introduced into the reaction vessel through the plasma space along the flow path F2. The RF power was 100 W.

In FIG. 4, a relationship between the flow rate of the carrier gas during introduction of ammonia gas and a loading effect (a difference in a film thickness between a center portion and a peripheral portion) for lower boats is shown (an average value from a fifth stage to a tenth stage from the lowermost stage).

As shown in FIG. 4, an influence of the loading effect is rarely appeared until the flow rate of the second carrier gas is up to 0.3 slm, but when the flow rate is more than that value, the influence of the loading effect is appeared. Therefore, it is found that, when a flow ratio of ammonia gas (NH₃) to N₂ gas is 50:3 or less, the loading effect can be suppressed.

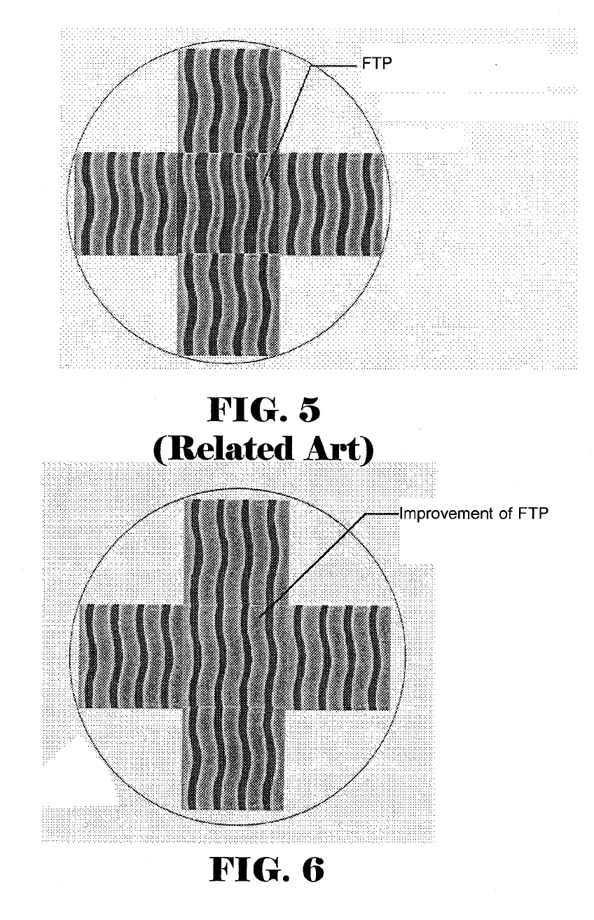

In FIGS. 5 and 6, deposition aspects of the center portion and the peripheral portions, when the N₂ gas is introduced at flow rates of 0.5 slm and 0.1 slm, are shown as a reference, respectively. In these figures, inspection results by a Scanning Electron Microscope (SEM) for the peripheral portions in each of four directions and the center portion are shown in a combined state. Obviously, a film thinning phenomenon (FTP) is caused in FIG. 5, while an improvement to the film thinning phenomenon can be found in FIG. 6.

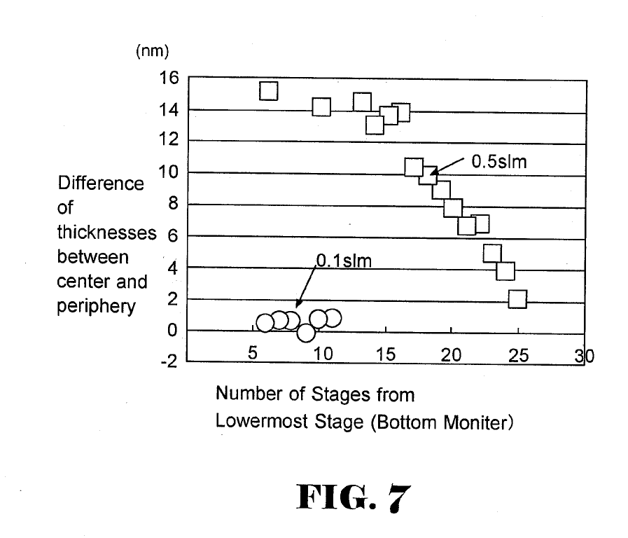

Also, a comparison of the difference in the film thickness between the center portion and the peripheral portions for each stage when the N₂ gas as the second carrier gas is introduced at flow rates of 0.5 slm and 0.1 slm is shown in FIG. 7.

As shown in FIG. 7, it is recognized that, when the flow rate of the N₂ gas is 0.5 slm, the film thinning phenomenon is gradually increased from the top portion to the bottom portion of the furnace, and when the flow rate is 0.1 slm, an improvement to the film thinning phenomenon in the bottom portion of the furnace is established. In the case of the flow rate of 0.1 slm, although the data for top portion of the furnace is not shown, an almost constant transition without any difference was observed.

Meanwhile, the flow rates of DCS and ammonia gas are not particularly limited, but are preferably 10 slm or less. Typically, the flow rate of ammonia gas is preferably two or more times that of DCS, particularly 2.5 times. Preferably, N₂ gas as a carrier gas is introduced to be less in the absolute value of the flow rate thereof during introduction of ammonia gas (as the second carrier gas) than during introduction of DCS (as the first carrier gas). The temperature during deposition of the nitride film is not particularly limited, but can be typically selected from a range of 300 to 800° C. When a nitride film is formed on a wiring which contains tungsten (W), the temperature is preferably 550° C. or less because a nitriding of tungsten can be prevented. In addition, the temperature is preferably 500° C. or more in that a quality of the nitride film to be formed, in particular an etching rate thereof as a protective film or an etching stopper film can be ensured.

The RF power of a high frequency power supply when activating the plasma can be set in a range of 50 to 300 W, and in particular is preferably approximately 100 W.

In the above description, although a silicon nitride film is formed as a nitride film, it should be understood that the invention is not limited to such an embodiment, but can be applied to other nitride films, for example a titanium nitride film, to be formed by the plasma-assisted ALD process.

What is claimed is:

1. A method for forming a nitride film by ALD process using a batch-type vertical furnace, wherein the batch-type vertical furnace comprises boats configured to allow semiconductor wafers to be disposed within a reaction vessel in a multistage manner, a plasma space located between RF electrodes disposed along side surfaces of the reaction vessel, and a supply port configured to approximately evenly supply a gas from the plasma space onto the semiconductor wafer in each stage within the reaction vessel, wherein the method is preformed by repeating a cycle until a desired film thickness is obtained, the cycle comprising:
supplying a source gas containing a source to be nitrided and a first carrier gas onto the semiconductor wafer in each stage, such that the source is adsorbed onto a surface of the semiconductor wafer;
purging the portion of the source gas not adsorbed;
introducing a nitriding gas and a second carrier gas from a bottom to a top of the plasma space such that a radical is generated, and then supplying a gas containing the generated radical onto the semiconductor wafer in each stage to nitrify the absorbed source; and
purging the nitriding gas;
wherein an amount of the second carrier gas supplied together with the nitriding gas is less than that of the first carrier gas supplied together with the source gas.

2. The method according to claim 1, wherein ammonia gas is used as the nitriding gas, nitrogen gas is used as the second carrier gas, and the amount of the second carrier gas during introduction of the nitriding gas is set at a flow ratio of the nitriding gas to the second carrier gas of 50:3 or less.

3. The method according to claim 1, wherein the nitride film is a silicon nitride film.

4. The method according to claim 2, wherein the nitride film is a silicon nitride film.

5. The method according to claim 3, wherein the source to be nitrided is dichlorosilane.

6. The method according to claim 4, wherein the source to be nitrided is dichlorosilane.

7. The method according to claim 1, wherein the silicon nitride film is formed on a wiring pattern containing tungsten formed on the semiconductor wafer.

8. The method according to claim 2, wherein the silicon nitride film is formed on a wiring pattern containing tungsten formed on the semiconductor wafer.

9. The method according to claim 3, wherein the silicon nitride film is formed on a wiring pattern containing tungsten formed on the semiconductor wafer.

10. The method according to claim 4, wherein the silicon nitride film is formed on a wiring pattern containing tungsten formed on the semiconductor wafer.

11. The method according to claim 5, wherein the silicon nitride film is formed on a wiring pattern containing tungsten formed on the semiconductor wafer.

12. The method according to claim 6, wherein the silicon nitride film is formed on a wiring pattern containing tungsten formed on the semiconductor wafer.

13. The method according to claim 7, wherein the nitride film is formed in a range of temperature of 500 to 550° C.

14. The method according to claim 8, wherein the nitride film is formed in a range of temperature of 500 to 550° C.

15. The method according to claim 9, wherein the nitride film is formed in a range of temperature of 500 to 550° C.

16. The method according to claim 10, wherein the nitride film is formed in a range of temperature of 500 to 550° C.

17. The method according to claim 11, wherein the nitride film is formed in a range of temperature of 500 to 550° C.

18. The method according to claim 12, wherein the nitride film is formed in a range of temperature of 500 to 550° C.
